(19) United States
(12) Patent Application Publication
(10) Pub. No.: US 2026/0029514 A1
(43) Pub. Date: Jan. 29, 2026

(54) OPTICAL DEVICE AND DISTANCE MEASURING DEVICE

(71) Applicant: Sony Group Corporation, Tokyo (JP)

(72) Inventors: Hiroshi TOBITA, Kanagawa (JP); Masato DOI, Kanagawa (JP); Masanao KAMATA, Tokyo (JP); Kenji TANAKA, Tokyo (JP); Jianglin YUE, Tokyo (JP); Gen YONEZAWA, Kanagawa (JP)

(21) Appl. No.: 18/996,503

(22) PCT Filed: Jul. 18, 2023
(86) PCT No.: PCT/JP2023/026300

§ 371 Date: Jan. 17, 2025

(30) Foreign Application Priority Data
Jul. 26, 2022 (JP) 2022-119075

(51) Int. Cl. G01S 7/481; G01S 7/484; G01S 7/4865; G01S 17/10; H01S 5/06; H01S 5/42

(52) U.S. Cl. CPC G01S 7/4815; G01S 7/4816; G01S 7/484; G01S 7/4865; G01S 17/10; H01S 5/0615; H01S 5/423

(57) ABSTRACT

An optical device and a distance measuring device capable of appropriately detecting an emission timing of oscillation light are provided. An optical device according to the present disclosure includes: a light emitting element including a semiconductor section that is included in a first resonator causing light of a first wavelength to resonate and causes the light of the first wavelength to oscillate, a solid-state laser medium that is included in the first resonator and a second resonator causing light of a second wavelength to resonate and causes the light of the second wavelength to oscillate, and a saturable absorber included in the second resonator and emitting the light of the second wavelength; a detector detecting the light of the first wavelength or a drive current of the light emitting element; and an emission timing detecting unit detecting an emission timing of the light of the second wavelength on the basis of a detection result of the light of the first wavelength or the drive current of the light emitting element acquired using the detector.

### TECHNICAL FIELD

The present disclosure relates to an optical device and a distance measuring device.

### BACKGROUND ART

Technologies of short pulse lasers are employed in the field of distance measurement and the like. For example, Q-switched solid-state laser elements can achieve a high peak power exceeding kW (kilowatts) with a relatively simple configuration and thus are used as light sources for distance measuring devices of a direct Time of Flight (dToF) system.

### CITATION LIST

### Patent Literature

### [PTL 1]

WO 2021/106757

### [PTL 2]

JP 2000-269598A

### [PTL 3]

WO 2021/051814

### SUMMARY

### Technical Problem

When a Q-switched laser element is used in dToF, in order to determine an emission time of oscillation light, it is necessary to extract a part of the oscillation light and detect it using a photodetector. For example, in a case in which a Q-switched laser element of which the wavelength of excitation light is 940 nm, and the wavelength of oscillation light is 1030 nm is used in dToF, in order to detect an emission time of the oscillation light with high sensitivity, a high-priced photodetector such as an InGaAs photodetector having a sensitivity level at 1030 nm is necessary. In addition, in order to detect an emission time of oscillation light, a mirror reflecting the oscillation light and a photodetector detecting the oscillation light are necessary, and thus there are problems that it is difficult to decrease the size of the distance measuring device, and the impact resistance of the distance measuring device is weak. In addition, in a case in which Q-switched laser elements are configured as an array, there are problems that it is difficult to arrange a mirror and a photodetector, and the emission time of oscillation light of each pixel cannot be accurately detected due to light leakage between pixels.

In order to decrease the size of the distance measuring device, a Vertical Cavity Surface Emitting Laser (VCSEL) element of which the wavelength is 1030 nm may be considered to be used as a light source. However, in such a case, there is a problem that high power as in the case of a Q-switched laser element cannot be acquired.

The present disclosure provides an optical device and a distance measuring device capable of appropriately detecting an emission timing of oscillation light.

### Solution to Problem

An optical device according to a first aspect of the present disclosure includes: a light emitting element including a semiconductor section that is included in a first resonator causing light of a first wavelength to resonate and causes the light of the first wavelength to oscillate, a solid-state laser medium that is included in the first resonator and a second resonator causing light of a second wavelength to resonate and causes the light of the second wavelength to oscillate, and a saturable absorber included in the second resonator and emitting the light of the second wavelength: a detector detecting the light of the first wavelength or a drive current of the light emitting element; and an emission timing detecting unit detecting an emission timing of the light of the second wavelength on the basis of a detection result of the light of the first wavelength or the drive current of the light emitting element acquired using the detector. In accordance with this, for example, by using a detection result of light (excitation light) of the first wavelength or a drive current of the light emitting element, the emission timing of the light (oscillation light) of the second wavelength can be appropriately detected.

In addition, in this first aspect, an intensity of the light of the first wavelength or a value of the drive current of the light emitting element may be changed in accordance with the emission timing of the light of the second wavelength. In accordance with this, for example, by using that the intensity of light of the first wavelength or a value of the drive current of the light emitting element changes in accordance with an emission timing of light of the second wavelength, the emission timing of the light of the second wavelength can be appropriately detected.

In addition, the optical device according to this first aspect may further include a distance measuring unit performing distance measurement on the basis of a detection result of the emission timing of the light of the second wavelength acquired using the emission timing detecting unit. In accordance with this, for example, appropriate distance measurement can be performed on the basis of an appropriate detection result of the emission timing.

In addition, the optical device according to this first aspect may further include a light receiving element receiving reflective light of the light of the second wavelength, in which the distance measuring unit may perform the distance measurement on the basis of a detection result of the emission timing of the light of the second wavelength acquired using the emission timing detecting unit and a light reception result of the reflective light acquired using the light receiving element. In accordance with this, for example, appropriate distance measurement can be performed from a light reception result on the basis of an appropriate detection result of the emission timing.

In addition, the optical device according to this first aspect may further include a light reception timing detecting unit detecting a light reception timing of the reflective light on the basis of a light reception result of the reflective light acquired using the light receiving element, in which the distance measuring unit may perform the distance measurement on the basis of a detection result of the emission timing of the light of the second wavelength acquired using the emission timing detecting unit and a detection result of the light reception timing of the reflective light acquired using the light reception timing detecting unit. In accordance with this, for example, appropriate distance measurement can be performed on the basis of an appropriate detection result of emission and light reception timings.

In addition, the optical device according to this first aspect may further include a difference detecting unit detecting a difference between the emission timing of the light of the second wavelength and the light reception timing of the reflective light, in which the distance measuring unit may perform the distance measurement on the basis of the difference detected using the difference detecting unit. In accordance with this, for example, by appropriately detecting a difference between emission and light reception timings, appropriate distance measurement can be performed on the basis of the difference.

In addition, in this first aspect, the optical device may be a distance measuring device performing distance measurement on the basis of a detection result of the emission timing of the light of the second wavelength acquired using the emission timing detecting unit. In accordance with this, for example, a distance measuring device performing appropriate distance measurement can be provided.

In addition, in this first aspect, the optical device may be a light emitting device emitting the light of the second wavelength and be included in a distance measuring device together with a light receiving device receiving the light of the second wavelength. In accordance with this, for example, a light emitting device that can realize appropriate distance measurement can be provided.

In addition, in this first aspect, the light emitting element may include: a first reflective layer that is positioned within the semiconductor section and reflects the light of the first wavelength; a second reflective layer that is positioned on a first face of the solid-state laser medium and reflects the light of the second wavelength; a third reflective layer that is positioned on a second face of the solid-state laser medium and reflects the light of the first wavelength: a fourth reflective layer that is positioned on a surface of the saturable absorber and reflects the light of the second wavelength: and a fifth reflective layer that is positioned within the semiconductor section, is positioned on a solid-state laser medium side of the first reflective layer, and reflects a part of the light of the first wavelength. In accordance with this, for example, first and second resonators can be realized using such reflective layers.

In addition, in this first aspect, the detector may be arranged on a second resonator side of the light emitting element. In accordance with this, for example, a substrate can be arranged on one side of the light emitting element, and the detector can be arranged on the other side of the light emitting element.

In addition, in this first aspect, the detector may be arranged on a first resonator side of the light emitting element. In accordance with this, for example, a substrate can be arranged on one side of the light emitting element, and the detector can be arranged inside the substrate or on the substrate.

In addition, in this first aspect, the detector may be mounted in the light emitting element. In accordance with this, for example, a structure in which the light emitting element and the detector are integrated together can be realized.

In addition, in this first aspect, the light emitting element may be disposed on a first face side of a substrate, and the detector may be disposed on the first face side of the substrate and be disposed inside a layer disposed between the substrate and the light emitting element. In accordance with this, for example, the detector can be arranged near the light emitting element.

In addition, in this first aspect, the light emitting element may be disposed on a first face side of a substrate, and the detector may be disposed inside a layer disposed on a second face side of the substrate. In accordance with this, for example, the light emitting element and the detector can be disposed on different faces of the substrate.

In addition, in this first aspect, the optical device may include a plurality of light emitting elements arranged in an array form as the light emitting element. In accordance with this, for example, distance measurement can be performed using an image.

In addition, in this first aspect, the optical device may further include a plurality of detectors arranged in an array form inside a same layer as that of the detector described above. In accordance with this, for example, detectors having 1 to 1 correspondence with the light emitting elements can be simply formed.

In addition, the optical device according to this first aspect may further include a driving unit driving the plurality of light emitting elements, and the driving unit may sequentially excite light from the plurality of light emitting elements by scanning the plurality of light emitting elements. In accordance with this, for example, the configuration of the driving unit can be simplified.

In addition, the optical device according to this first aspect may further include a driving unit driving the plurality of light emitting elements, and the driving unit may simultaneously excite light from the plurality of light emitting elements by simultaneously driving the plurality of light emitting elements. In accordance with this, for example, such light emitting elements can be driven in a short time.

A distance measuring device according to a second aspect of the present disclosure includes: a light emitting element including a semiconductor section that is included in a first resonator causing light of a first wavelength to resonate and causing the light of the first wavelength to oscillate, a solid-state laser medium that is included in the first resonator and a second resonator causing light of a second wavelength to resonate and causes the light of the second wavelength to oscillate, and a saturable absorber included in the second resonator and emitting the light of the second wavelength: a detector detecting the light of the first wavelength or a drive current of the light emitting element; a light receiving element receiving reflective light of the light of the second wavelength; and a distance measuring unit performing distance measurement on the basis of a detection result of the light of the first wavelength or a drive current of the light emitting element acquired using the detector and a light reception result of the reflective light acquired using the light receiving element.

In accordance with this, for example, by using a detection result of reflective light of light (excitation light) of the first wavelength or a drive current of the light emitting element, appropriate distance measurement can be performed by appropriately detecting the emission timing of the light (oscillation light) of the second wavelength.

In addition, the distance measuring device according to this second aspect may further include an emission timing detecting unit detecting an emission timing of the light of the second wavelength on the basis of a detection result of the light of the first wavelength or the drive current of the light emitting element acquired using the detector, and the distance measuring unit may perform the distance measurement on the basis of a detection result of the emission timing of the light of the second wavelength acquired using the emission timing detecting unit and a light reception result of the reflective light acquired using the light receiving element. In accordance with this, for example, appropriate distance measurement can be performed by appropriately detecting the emission timing of the light of the second wavelength.

### BRIEF DESCRIPTION OF DRAWINGS

FIG. 1 is a schematic view illustrating the structure of a distance measuring device 100 according to a first embodiment.

FIG. 2 is a cross-sectional view for describing the structure of a light emitting element 1 according to the first embodiment.

FIG. 3 is a block diagram illustrating the structure of the distance measuring device 100 according to the first embodiment.

FIG. 4 is a block diagram illustrating the structure of a distance measuring device 100 of a modified example of the first embodiment.

FIG. 5 is a graph for describing an operation of the light emitting element 1 according to the first embodiment.

FIG. 6 is a cross-sectional view illustrating the structure of a light emitting element 1 of a modified example of the first embodiment.

FIG. 7 is a cross-sectional view illustrating the structure of the light emitting element 1 of the modified example of the first embodiment.

FIG. 8 is a schematic view illustrating the structure of a distance measuring device 100 of a modified example of the first embodiment.

FIG. 9 is a block diagram illustrating the structure of the distance measuring device 100 of the modified example of the first embodiment.

FIG. 10 is a perspective view illustrating the structure of a light emitting device 101 according to a second embodiment.

FIG. 11 is a perspective view illustrating the structure of a light emitting device 101 of a comparative example of the second embodiment.

FIG. 12 is a cross-sectional view illustrating the structure of a light emitting device 101 of a modified example of the second embodiment.

FIG. 13 is a schematic view illustrating the structure of a distance measuring device 100 according to the second embodiment.

FIG. 14 is a block diagram illustrating the structure of the distance measuring device 100 according to the second embodiment.

FIG. 15 is a block diagram illustrating the structure of a distance measuring device 100 of a modified example of the second embodiment.

FIG. 16 is a block diagram illustrating the structure of the distance measuring device 100 of the modified example of the second embodiment.

FIG. 17 is a block diagram illustrating the structure of a distance measuring device 100 according to a third embodiment.

FIG. 18 is a block diagram illustrating the structure of a distance measuring device 100 of a modified example of the third embodiment.

### DESCRIPTION OF EMBODIMENTS

Hereinafter, embodiments of the present disclosure will be described with reference to the drawings.

### First Embodiment

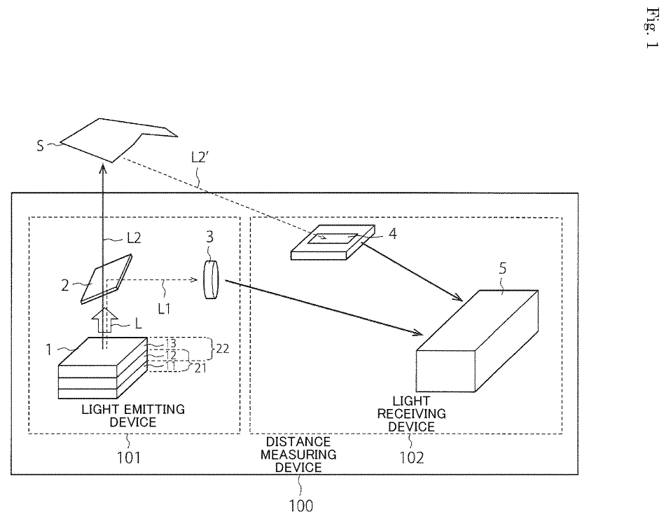

FIG. 1 is a schematic view illustrating the structure of a distance measuring device 100 according to a first embodiment.

As illustrated in FIG. 1, the distance measuring device 100 includes a light emitting device 101 and a light receiving device 102. The distance measuring device 100 emits light emitted from the light emitting device 101 onto a subject S and receives light reflected on the subject S using the light receiving device 102. The distance measuring device 100 performs distance measurement for the subject S, in other words, measures a distance between the subject S and the distance measuring device 100.

The light emitting device 101 includes a light emitting element 1, a half mirror 2, and a photodiode (PD) 3. The light receiving device 102 includes a light receiving element 4 and an arithmetic operation circuit 5. The photodiode 3 and the arithmetic operation circuit 5 are respective examples of a detector and a distance measuring unit of the present disclosure.

The light emitting element 1 includes a semiconductor section 11, a solid-state laser medium 12, and a saturable absorber (Q-switch) 13. The semiconductor section 11 and the solid-state laser medium 12 form a resonator 21, and the solid-state laser medium 12 and the saturable absorber 13 form a resonator 22. The resonators 21 and 22 are respective examples of first and second resonators of the present disclosure.

The semiconductor section 11 causes light having a predetermined wavelength to oscillate. This light is used for exciting the solid-state laser medium 12 and thus is called excitation light. The wavelength of the excitation light, for example, is 940 nm. This wavelength is an example of a first wavelength of the present disclosure. The excitation light is also called an excitation laser.

The solid-state laser medium 12 is excited by excitation light, thereby causing light having a predetermined wavelength different from the wavelength of the excitation light to oscillate. This light corresponds to oscillation light as a Q-switched solid-state laser element and thus is called oscillation light. The wavelength of the oscillation light, for example, is 1030 nm. This wavelength is an example of a second wavelength of the present disclosure. The oscillation light is also called as an oscillation laser.

The saturable absorber 13 has the function of absorbing a part of light generated inside the semiconductor section 11 and the solid-state laser medium 12 and the function of discharging a part of light generated inside the semiconductor section 11 and the solid-state laser medium 12 to the outside. For example, the oscillation light generated inside the solid-state laser medium 12 passes through the saturable absorber 13, thereby being discharged from the saturable absorber 13 to the outside. This light becomes emission light emitted from the light emitting element 1.

The resonator 21 includes the semiconductor section 11 and the solid-state laser medium 12 and causes light having a wavelength of 940 nm to resonate. The resonator 22 includes the solid-state laser medium 12 and the saturable absorber 13 and causes light having a wavelength of 1030 nm to resonate. Thus, the light emitting element 1 according to this embodiment can generate light having a wavelength of 1030 nm as oscillation light by generating light having a wavelength of 940 nm as excitation light. In addition, the resonant wavelength of the resonator 21 may be a wavelength other than 940 nm, and the resonant wavelength of the resonator 22 may be a wavelength other than 1030 nm. Such resonators 21 and 22 share the solid-state laser medium 12 and thus overlap each other in the area of the solid-state laser medium 12.

FIG. 1 illustrates light L emitted from the light emitting element 1. Although this light L mainly includes light L2 corresponding to oscillation light, furthermore, the light L also includes light L1 corresponding to excitation light. The wavelength of the light L1, for example, is 940 nm. The wavelength of the light L2, for example, is 1030 nm. Additional details of the light emitting element 1 will be described below.

The half mirror 2 is arranged at a position in which the light L is incident and separates the light L into light L1 and light L2. The light L1 is supplied to the photodiode 3. The light L2 is emitted from the light emitting device 101 and becomes emission light emitted to a subject S. In FIG. 1, the light L2 is emitted to the subject S, and light L2′ that is reflective light of the light L2 is directed from the subject S to the light receiving device 102.

The photodiode 3 is arranged at a position in which the light L1 is incident, detects the light L1, and outputs a signal representing a detection result of the light L1. For example, the photodiode 3 receives the light L1, performs photoelectric conversion, and outputs signal electric charge generated through the photoelectric conversion. A signal output from the photodiode 3 is input to the arithmetic operation circuit 5. This signal may be either a current signal acquired from the signal electric charge described above or a voltage signal acquired from the signal electric charge described above.

The light receiving element 4 receives light L2′ from the subject S and outputs a signal representing a light reception result of the light L2′. The light receiving element 4, for example, is a photodiode and outputs a signal acquired through photoelectric conversion of the light L2′. The signal output from the light receiving element 4 is input to the arithmetic operation circuit 5.

The arithmetic operation circuit 5 performs various arithmetic operations relating to distance measurement and other information processing. The arithmetic operation circuit 5, for example, performs distance measurement for a subject S on the basis of the above-described signal input from the photodiode 3 and the above-described signal input from the light receiving element 4. Additional details of the arithmetic operation circuit 5 will be described below.

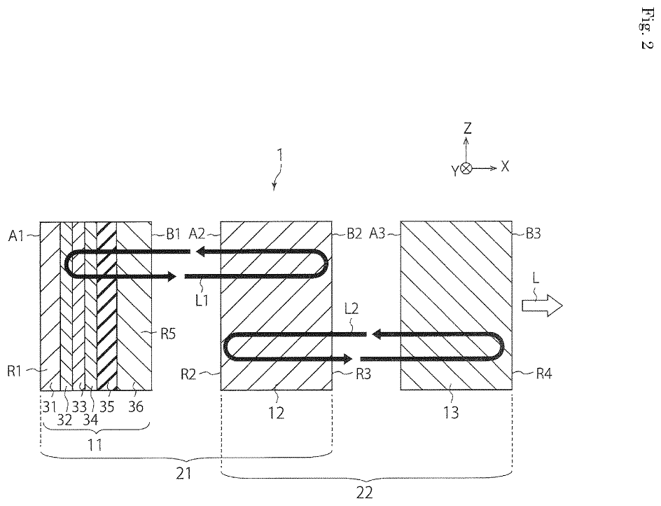

FIG. 2 is a cross-sectional view for describing the structure of the light emitting element 1 according to the first embodiment.

As described above, the light emitting element 1 includes the semiconductor section 11, the solid-state laser medium 12, and the saturable absorber 13. In the light emitting element 1 according to this embodiment, although the semiconductor section 11 and the solid-state laser medium 12 are brought into contact with each other, and the solid-state laser medium 12 and the saturable absorber 13 are brought into contact with each other, in FIG. 2, for easy understanding of description, the semiconductor section 11 and the solid-state laser medium 12 are drawn with being separated from each other, and the solid-state laser medium 12 and the saturable absorber 13 are drawing with being separated from each other. The semiconductor section 11 and the solid-state laser medium 12 form the resonator 21, and the solid-state laser medium 12 and the saturable absorber 13 form the resonator 22.

FIG. 2 illustrates an X axis, a Y axis, and a Z axis that are perpendicular to each other, an X direction and a Y direction correspond to a horizontal direction, and a Z direction corresponds to a vertical direction. In FIG. 2, although the semiconductor section 11, the solid-state laser medium 12, and the saturable absorber 13 are arranged in order in the X direction, they may be arranged in order in any other direction.

FIG. 2 illustrates a surface Al of the semiconductor section 11 in a-X direction, a surface B1 of the semiconductor section 11 in a +X direction, a surface A2 of the solid-state laser medium 12 in the-X direction, a surface B2 of the solid-state laser medium 12 in the +X direction, a surface A3 of the saturable absorber 13 in the-X direction, and a surface B3 of the saturable absorber 13 in the +X direction. In the light emitting element 1 according to this embodiment, the surface B1 of the semiconductor section 11 is brought into contact with the surface A2 of the solid-state laser medium 12, and the surface B2 of the solid-state laser medium 12 is brought into contact with the surface A3 of the saturable absorber 13.

The semiconductor section 11 includes an n Distributed Bragg Reflector (DBR) layer 31, a cladding layer 32, an active layer 33, a cladding layer 34, an oxide layer 35, and a p-DBR layer 36 in order. In FIG. 2, the n-DBR layer 31 is positioned on the surface A1 side, and the p-DBR layer 36 is positioned on the surface B1 side. In addition, as in an example to be described below, the semiconductor layer 11 may include the n-DBR layer 31 on the surface B1 side and include the p-DBR layer 36 on the surface A1 side.

The n-DBR layer 31 includes a plurality of low-refractive index layers and a plurality of high-refractive index layers that are alternately stacked. These low-refractive index layers and high-refractive index layers are respectively, for example, Al_{z1}Ga_{1-z1}As layers and Al_{z2}Ga_{1-z2}As layers. Here, Al, Ga, and As respectively represent aluminum, gallium, and arsenic. In addition, z1 and z2 are real numbers that satisfy “0≤z1<z2≤1,” and it is preferable that z2 be less than 1. The n-DBR layer 31 further contains an n-type dopant (for example, silicon).

The cladding layer 32, for example, is a non-doped AlGaAs layer.

The active layer 33 has a quantum well structure and, more specifically, includes a plurality of quantum well layers and a plurality of barrier layers that are alternately stacked to have compressive strain. These quantum well layers and barrier layers are, for example, respectively Alₓ₁In_{y1}Ga_{1-x1-y1}As layers and Alₓ₂In_{y2}Ga_{1-x2-y2}As layers. Here, In represents indium. In addition, x1, y1, x2, and y2 are real numbers that satisfy “0≤x1, y1, x2, y2≤1” and “0≤x1+y1≤1” and “0≤x2+y2≤1.” The active layer 33 may have a multi-junction structure through a tunnel junction.

The cladding layer 34 is, for example, a non-doped AlGaAs layer.

The oxide layer 35 includes, for example, includes an AlAs layer and an Al₂O₃ layer obtained by oxidizing the AlAs layer (here, O represents oxygen). The oxidation from the AlAs layer to the Al₂O₃ layer is performed, for example, using water vapor. By using the oxide layer 35, electrical and optical confinement can be performed. In addition, the oxide layer 35 according to this embodiment has a cylindrical opening portion (not illustrated) penetrating through the oxide layer 35 in a center portion of the oxide layer 35 in a plan view.

The p-DBR layer 36 includes a plurality of low-refractive index layers and a plurality of high-refractive index layers that are alternately stacked. These low-refractive-index layers and high-refractive-index layers are respectively, for example, Al_{z3}Ga_{1-z3}As layers and Al_{z4}Ga_{1-z4}As layers. Here, z3 and z4 are real numbers satisfying “0≤z3<z4≤1,” and it is preferable that z4 be less than 1. The p-DBR layer 36 further contains a p-type dopant (for example, carbon).

The semiconductor section 11 further includes an n-contact layer (not illustrated) in the-X direction of the n-DBR layer 31 and a p-contact layer (not illustrated) in the +X direction of the p-DBR layer 36. The n-contact layer is, for example, a GaAs layer containing an n-type dopant and is in contact with an n-metal layer (not illustrated) that functions as a metal electrode. The p-contact layer is, for example, a GaAs layer containing a p-type dopant and is in contact with a p-metal layer (not illustrated) that functions as a metal electrode.

The solid-state laser medium 12 is, for example, an Yb: YAG crystal, that is, a YAG (Yttrium Aluminum Garnet) crystal doped with Yb (Ytterbium). In this case, the resonant wavelength of the resonator 21 is 940 nm, and the resonant wavelength of the resonator 22 is 1030 nm. The solid-state laser medium 12 may be formed as any one of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and YB:YAB. In addition, the solid-state laser medium 12 may be a four-level laser medium or a three-level laser medium.

The saturable absorber 13 is, for example, a Cr:YAG crystal, that is, a YAG crystal doped with Cr (chromium). The saturable absorber 13 is also called as a Q switch. The Q switch is a material that exhibits a saturable absorption property for the optical intensity of a laser beam passing through the inside of the Q switch. The saturable absorber 13 may also be a V:YAG crystal, that is, a YAG crystal doped with V (vanadium). The saturable absorber 13 may also be formed from a material capable of realizing an active Q switch element.

In this embodiment, the semiconductor section 11 causes excitation light to oscillate through surface emission from the active layer 33 and excites the solid-state laser medium 12 using the excitation light. The solid-state laser medium 12 causes oscillation light to oscillate by being excited using excitation light. The oscillation light passes through the saturable absorber 13 and is discharged to the outside from the saturable absorber 13. As a result, light is emitted from the light emitting element 1.

As illustrated in FIG. 2, the light emitting element 1 further includes reflective layers R1, R2, R3, R4, and R5. The reflective layers R1, R2, R3, R4, and R5 are respective examples of first, second, third, fourth, and fifth reflective layers of the present disclosure.

The reflective layer R1 is formed using the n-DBR layer 31 and functions as a high-reflective layer for light of 940 nm. The reflective layer R3 is formed on a surface B2 of the solid-state laser medium 12 and functions as a high-reflective layer for light of 940 nm. The surface B2 is an example of a second face of the solid-state laser medium 12 of the present disclosure. The reflective layer R3, for example, is configured as a Long Wave Pass Filter (LWPF). The reflective layer R5 is formed using the p-DBR layer 36 and functions as a partial reflective layer having high reflectivity for light of 940 nm. For example, this reflectivity is about 95%. In this way, the reflective layers R1, R3, and R5 are capable of reflecting light of 940 nm. The resonator 21 according to this embodiment is realized by such reflective layers R1, R3, and R5. The resonator 21 according to this embodiment is configured as a resonator of VCSEL that is a semiconductor laser of a surface-emitting laser type. FIG. 2 schematically illustrates an appearance of light (L1) of 940 nm being generated between the reflective layer R1 and the reflective layer R3.

The reflective layer R2 is formed on a surface A2 of the solid-state laser medium 12 and functions as a high-reflective layer for light of 1030 nm. The surface A2 is an example of a first face of the solid-state laser medium 12 of the present disclosure. The reflective layer R2, for example, is configured as a Short Wave Pass Filter (SWPF). The reflective layer R4 is formed on a surface B3 of the saturable absorber 13 and functions as a partial reflective layer for light of 1030 nm. In this way, the reflective layers R2 and R4 are capable of reflecting light of 1030 nm. The resonator 22 according to this embodiment is realized by such reflective layers R2 and R4. The resonator 22 according to this embodiment is configured as a resonator of the Q-switched solid-state laser. FIG. 2 schematically illustrates an appearance of light (L2) of 1030 nm being generated between the reflective layer R2 and the reflective layer R4.

In this embodiment, light having a wavelength of 940 nm is used as excitation light used for exciting the solid-state laser medium 12. For this reason, the reflective layer R3 according to this embodiment is configured as a high-reflective layer, and, in accordance with this, the power of the excitation light can be confined within the resonator 21. The resonator 21 according to this embodiment is configured as a coupled resonator (Coupled Cavity) including three reflective layers R1, R3, and R5. The reflective layer R5 is called as a middle reflective layer and has a constant transmittance for excitation light.

On the other hand, the reflective layer R4 is configured as a partial reflective layer. When the solid-state laser medium 12 is excited by excitation light, the resonator 22 reaches Q-switched laser pulse oscillation. As a result, light having a wavelength of 1030 nm is generated as oscillation light. The oscillation light passes through the reflective layer R4 and is emitted as emission light of the light emitting element 1. In addition, the reflective layer R4 may be disposed at a place other than the surface B3 of the saturable absorber 13 as long as it is disposed in the +X direction of the surface B3 of the saturable absorber 13.

In addition, the resonator 22 may include a wavelength conversion material used for converting the wavelength of oscillation light from 1030 nm to a value other than 1030 nm. The wavelength conversion material, for example, is a nonlinear optical crystal of LiNbO₃, BBO, LBO, CLBO, BiBO, KTP, SLT, or the like. The wavelength conversion material may also be a phase-matching material similar to such nonlinear optical crystals. In addition, the resonator 22 may include an optical filter, a polarizer, a diffraction grating, or the like.

Here, an operation example of the light emitting element 1 according to this embodiment will be described.

When a current is injected into the active layer 33 from an electrode disposed in the semiconductor section 11, laser oscillation oscillating excitation light occurs. As a result, the solid-state laser medium 12 is excited by the excitation light, and light is generated from the solid-state laser medium 12. However, since the resonator 22 includes the saturable absorber 13, immediately after the excitation of the solid-state laser medium 12, the light generated from the solid-state laser medium 12 (spontaneously-emitted light) is partially absorbed by the saturable absorber 13. Therefore, the optical feedback according to the reflective layer R4 does not reach an oscillation threshold, and the resonator 22 does not reach Q-switched laser oscillation.

Thereafter, when the solid-state laser medium 12 comes into a sufficiently-excited state, the output of the spontaneously-emitted discharge light from the solid-state laser medium 12 is raised. When the output of the spontaneously-emitted light exceeds a certain value, the light absorption rate of the saturable absorber 13 is sharply lowered. As a result, the spontaneously-emitted light from the solid-state laser medium 12 has a reduced loss in the saturable absorber 13, and resonance occurs between the reflective layer R2 and the reflective layer R4. This causes induced discharge in the solid-state laser medium 12. In accordance with this, the resonator 22 reaches Q-switched laser oscillation and discharges a Q-switched laser pulse from the reflective layer R4. This light becomes emission light from the light emitting element 1.

In addition, the light emitting element 1 may be arranged on a semiconductor substrate such as a GaAs substrate or the like. In this case, the light emitting element 1 may be arranged to form a top-emission type with respect to the semiconductor substrate or may be arranged to form a bottom-emission type.

In addition, although the light emitting element 1 illustrated in FIG. 2 is disposed inside the distance measuring device 100 illustrated in FIG. 1, it may be used for purposes other than distance measurement. For example, the light emitting element 1 illustrated in FIG. 2 may be disposed inside a medical device for provision for a medical use.

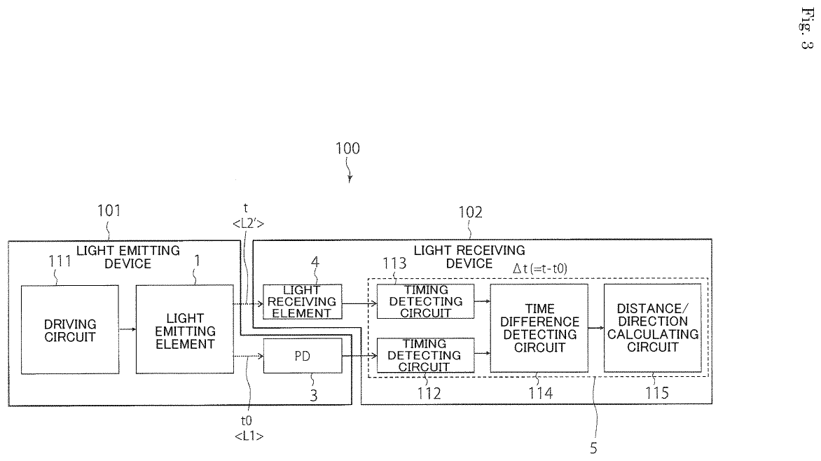

FIG. 3 is a block diagram illustrating the structure of the distance measuring device 100 according to the first embodiment.

Similar to FIG. 1, FIG. 3 illustrates a light emitting element 1, a photodiode 3, a light receiving element 4, and an arithmetic operation circuit 5 inside the distance measuring device 100, and illustration of a half mirror 2 is omitted. In addition, the distance measuring device 100, as illustrated in FIG. 3, includes a driving circuit 111 that is an example of a driving unit, a timing detecting circuit 112 that is an example of an emission timing detecting unit, a timing detecting circuit 113 that is an example of a light reception timing detecting unit, a time difference detecting circuit 114 that is an example of a difference detecting unit, and a distance/direction calculating circuit 115 that is an example of a distance measuring unit. The driving circuit 111 is included inside the light emitting device 101, and the timing detecting circuit 112, the timing detecting circuit 113, the time difference detecting circuit 114, and the distance/direction calculating circuit 115 are included inside the arithmetic operation circuit 5 of the light receiving device 102.

The driving circuit 111 is a circuit that drives the light emitting element 1. When driving the light emitting element 1, the driving circuit 111 supplies a current (a drive current) to an electrode disposed in the semiconductor section 11. As a result, a current is injected into the active layer 33, and light L (FIG. 1) is emitted from the light emitting element 1. As described above, the light L emitted from the light emitting element 1 includes not only light L2 corresponding to oscillation light but also light L1 corresponding to excitation light. The photodiode 3 outputs a signal representing a detection result of the light L1, and the light receiving element 4 outputs a signal representing a light reception result of light L2′ that is reflective light of the light L2.

The timing detecting circuit 112 receives a signal representing a detection result of light L1 from the photodiode 3. In addition, the timing detecting circuit 112 detects an emission timing of the light L2 on the basis of the detection result of the light L1. The emission timing of the light L2 is a timing at which the light L2 is emitted from the light emitting element 1. The timing detecting circuit 112, for example, detects an emission time to of the light L2 from the light emitting element 1 as an emission timing of the light L2. In addition, the timing detecting circuit 112 may detect an emission timing in a form other than the emission time to.

As a result of review, it has been understood that the intensity of the light L1 emitted from the light emitting element 1 changes in accordance with an emission timing of the light L2 from the light emitting element 1. For example, it has been checked that the intensity of the light L1 emitted from the light emitting element 1 changes in synchronization with the emission time to of the light L2 from the light emitting element 1. Thus, in order to detect the emission timing of the light L2, the timing detecting circuit 112 receives a signal representing a detection result of the light L1. According to this embodiment, by using the phenomenon that the intensity of the light L1 changes in accordance with the emission timing of the light L2, the emission timing of the light L2 can be detected from the detection result of the light L1. A signal received by the timing detecting circuit 112 from the photodiode 3, for example, is a signal representing the detection result of the intensity of the light L1.

The timing detecting circuit 113 receives a signal representing a light reception result of light L2′ from the light receiving element 4. The timing detecting circuit 113 detects a light reception timing of the light L2′ on the basis of the light reception result of the light L2′. The light reception timing of the light L2′ is a timing at which the light L2′ is received by the light receiving element 4. The timing detecting circuit 113, for example, detects a light reception time t of the light L2′ according to the light receiving element 4 as a light reception timing of the light L2′. In addition, the timing detecting circuit 113 may detect a light reception timing in a form other than that using the light reception time t.

The time difference detecting circuit 114 receives a signal representing an emission timing of the light L2 from the timing detecting circuit 112 and receives a signal representing a light reception timing of the light L2′ from the timing detecting circuit 113. In addition, the time difference detecting circuit 114 detects a difference between the emission timing of the light L2 and the light reception timing of the light L2′. This difference, for example, is a time difference At between the emission time to of the light L2 and the light reception time t of the light L2′ (Δt=t−t0).

The distance/direction calculating circuit 115 receives the difference between the emission timing of the light L2 and the light reception timing of the light L2′ from the time difference detecting circuit 114. In addition, the distance/direction calculating circuit 115 performs distance measurement for a subject S on the basis of the received difference. More specifically, the distance/direction calculating circuit 115 calculates a distance between the subject S and the distance measuring device 100 using the received difference. In a second embodiment to be described below, the distance/direction calculating circuit 115 further calculates a direction of the subject S with respect to the distance measuring device 100 using the received difference.

As described above, by using the phenomenon that the intensity of the light L1 changes in accordance with the emission timing of the light L2, the distance measuring device 100 according to this embodiment detects an emission timing of the light L2 from the detection result of the light L1. If the emission timing of the light L2 is to be detected from the detection result of the light L2, a high-priced photodetector (for example, an InGaAs photodetector) having sensitivity at 1030 nm needs to be employed. On the other hand, in a case in which an emission timing of the light L2 is to be detected from a detection result of the light L1, a low-priced photodetector (for example, a Si photodetector) having sensitivity at 940 nm can be employed. Thus, according to this embodiment, by using the phenomenon described above, the emission timing of the light L2 can be easily detected. The photodiode 3 according to this embodiment, for example, can be formed inside a Si (silicon) substrate.

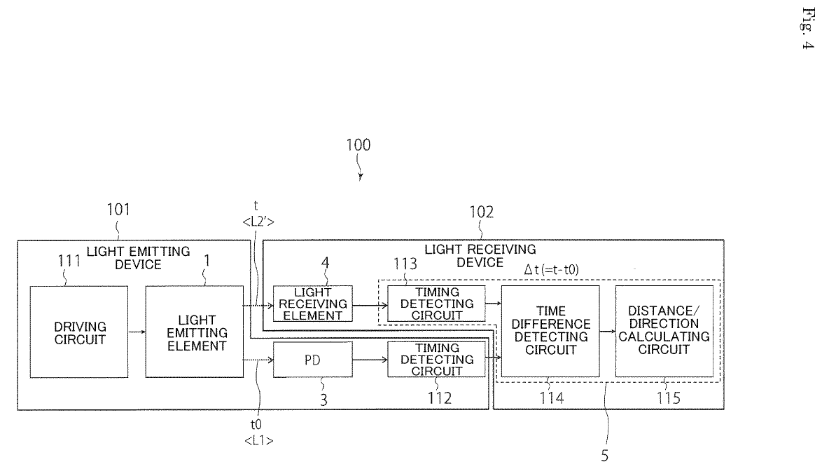

FIG. 4 is a block diagram illustrating the structure of a distance measuring device 100 of a modified example of the first embodiment.

The distance measuring device 100 (FIG. 4) of this modified example has a structure similar to the distance measuring device 100 illustrated in FIG. 3. However, the distance measuring device 100 of this modified example includes a timing detecting circuit 112 not inside the light receiving device 102 but inside the light emitting device 101. The arithmetic operation circuit 5 of this modified example, as illustrated in FIG. 4, includes a timing detecting circuit 113, a time difference detecting circuit 114, and a distance/direction calculating circuit 115. The distance measuring device 100 illustrated in FIG. 3, the distance measuring device 100 illustrated in FIG. 4, and the light emitting device 101 illustrated in FIG. 4 are examples of an optical device according to the present disclosure.

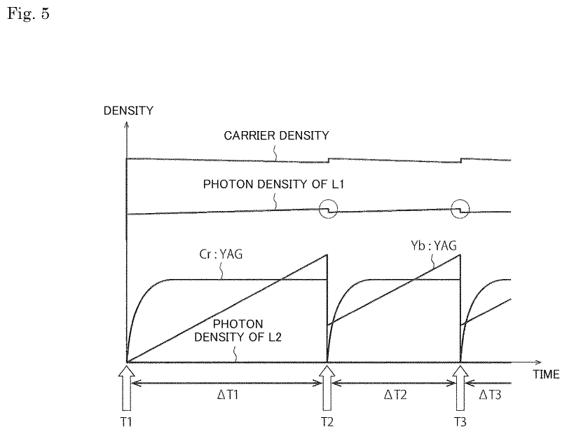

FIG. 5 is a graph for describing an operation of the light emitting element 1 according to the first embodiment.

FIG. 5 illustrates changes of a carrier density of a drive current, a photon density of light L1, and a photon density of light L2 with respect to time. In addition, FIG. 5 illustrates changes of an inverted distribution density of a solid-state laser medium 12 (Yb:YAG) and a carrier density of the ground level of a saturable absorber 13 (Cr:YAG) with respect to time.

Each white circle illustrated in FIG. 5 illustrates a timing at which the intensity of light L1 emitted from the light emitting element 1 is reduced. The reduction of the intensity of the light L1 occurs at a timing at which the light L2 (pulse light) is emitted from the light emitting element 1. Thus, by detecting a timing at which the intensity of the light L1 is reduced, an emission timing of the light L2 from the light emitting element 1 can be detected.

FIG. 5 illustrates an excitation start time T1 of the light L1, times T2 and T3 at which the intensity of the light L1 is reduced, and time differences ΔT1, ΔT2, and ΔT3 between such times. More specifically, ΔT1=T2−T1, ΔT2=T3−T2, and ΔT3=T4−T3 are satisfied (T4 represents a time at which the intensity of the light L1 is reduced after T3). Pulse light included in the light L2 is emitted from the light emitting element 1 at times T2, T3, and the like. The time differences ΔT1, ΔT2, and ΔT3 correspond to differences between emission times of pulse light included in the light L2. In addition, the photon density of the light L2 increases and decreases during extremely short times near the times T2 and T3 (for example, 0.01 ns to 1 ns).

Next, various modified examples of this embodiment will be described.

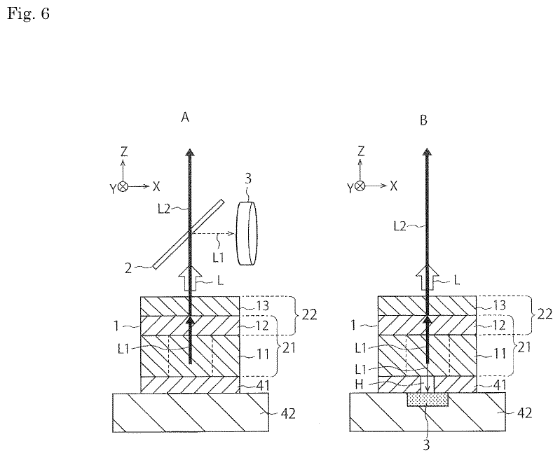

FIG. 6 is a cross-sectional view illustrating the structure of a light emitting element 1 of a modified example of the first embodiment.

In a modified example illustrated in A of FIG. 6, a light emitting element 1 is arranged on a substrate 42 through a p-metal layer 41. A semiconductor section 11, a solid-state laser medium 12, and a saturable absorber 13 of this modified example are disposed in order on the p-metal layer 41. The p-metal layer 41 is used as a metal electrode that supplies a current to an active layer 33. The substrate 42, for example, is a semiconductor substrate such as a SiC (silicon carbide) substrate or an insulating substrate such as an SiN (silicon nitride) substrate. In this modified example, a half mirror 2 and a photodiode 3 are arranged on the resonator 22 side of the light emitting element 1.

In a modified example illustrated in B of FIG. 6, a light emitting element 1 has a structure similar to the light emitting element 1 illustrated in A of FIG. 6. However, a photodiode 3 of this modified example is disposed inside a substrate 42 and, as a result, is arranged on the resonator 21 side of the light emitting element 1. The photodiode 3 of this modified example, as illustrated in B of FIG. 6, detects light L1 that is emitted from a lower face of the light emitting element 1 and passes through an opening portion H of a p-metal layer 41. The photodiode 3 of this modified example is disposed inside a substrate 42 mounted in the light emitting element 1, thereby being integrated with the light emitting element 1. According to this modified example, an alignment operation for the light emitting element 1, a half mirror 2, and the photodiode 3 can become unnecessary, the size of the distance measuring device 100 can be decreased, and shock resistance of the distance measuring device 100 can be improved.

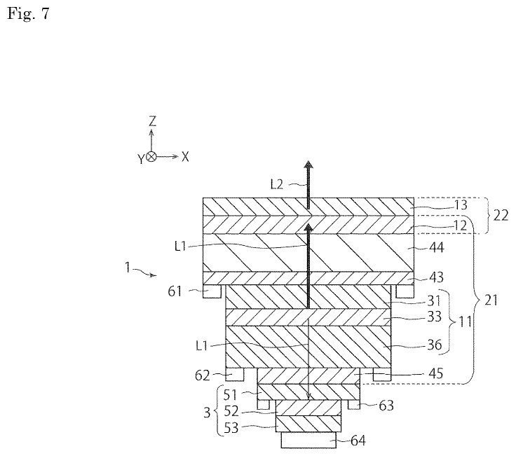

FIG. 7 is a cross-sectional view illustrating the structure of a light emitting element 1 of a modified example of the first embodiment.

The light emitting element 1 of this modified example includes the semiconductor section 11, the solid-state laser medium 12, and the saturable absorber 13 described above and further includes an n-contact layer 43, a substrate 44, and a non-doped semiconductor layer 45. In addition, FIG. 7 illustrates an n-DBR layer 31, an active layer 33, and a p-DBR layer 36 inside the semiconductor section 11, and illustration of a cladding layer 32, a cladding layer 34, and an oxide layer 35 is omitted. The n-contact layer 43 and the substrate 44 are disposed in order between the n-DBR layer 31 and the solid-state laser medium 12, and the non-doped semiconductor layer 45 is disposed between the n-DBR layer 31 and a photodiode 3 to be described below. The n-contact layer 43, the substrate 44, and the non-doped semiconductor layer 45, for example, are respectively a GaAs layer containing an n-type dopant, a GaAs substrate, and a non-doped GaAs layer. The non-doped semiconductor layer 45 is disposed to raise electrical resistance between the light emitting element 1 and the photodiode 3.

In addition, FIG. 7 illustrates the photodiode 3 mounted in the light emitting element 1. The photodiode 3 of this modified example includes an n-type semiconductor layer 51, an active layer 52, and a p-type semiconductor layer 53. The photodiode 3 of this modified example is arranged on the resonator 21 side of the light emitting element 1. The photodiode 3 of this modified example, as illustrated in FIG. 7, detects light L1 emitted from a lower face of the light emitting element 1. According to this modified example, an alignment operation for the light emitting element 1, a half mirror 2, and a photodiode 3 can become unnecessary, the size of the distance measuring device 100 can be decreased, and shock resistance of the distance measuring device 100 can be improved. The n-type semiconductor layer 51, the active layer 52, and the p-type semiconductor layer 53, for example, are respectively a GaAs layer containing n-type dopants, a layer having a quantum well structure, and a GaAs layer containing p-type dopants.

In addition, FIG. 7 illustrates an n-metal layer 61 disposed on a lower face of the n-contact layer 43, a p-metal layer 62 disposed on a lower face of the p-DBR layer 36, an n-metal layer 63 disposed on a lower face of the n-type semiconductor layer 51, and a p-metal layer 64 disposed on a lower face of the p-type semiconductor layer 53. The n-metal layer 61, the p-metal layer 62, and the n-metal layer 63 have a ring shape, and the p-metal layer 64 has a disk shape. The n-metal layer 61 and the p-metal layer 62 function as metal electrodes used for driving the semiconductor section 11, and the n-metal layer 63 and the p-metal layer 64 function as metal electrodes used for outputting a signal from the photodiode 3.

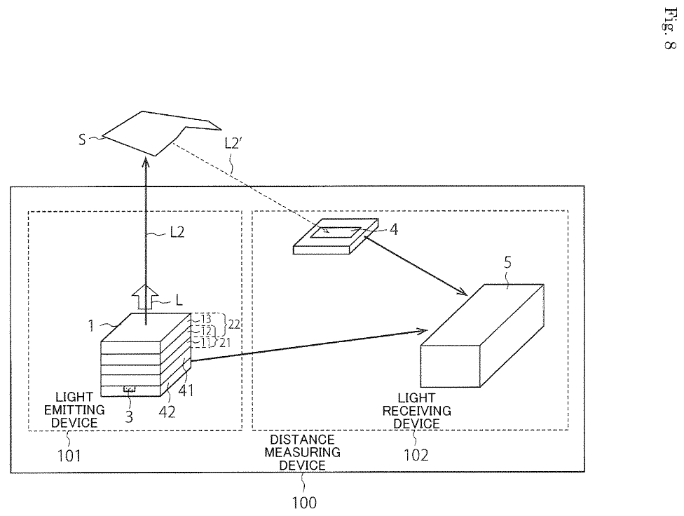

FIG. 8 is a schematic view illustrating the structure of a distance measuring device 100 of a modified example of the first embodiment.

The distance measuring device 100 (FIG. 8) of this modified example has a structure similar to the distance measuring device 100 illustrated in FIG. 1. However, similar to the light emitting element 1 illustrated in B of FIG. 6, a light emitting element 1 of this modified example is arranged on a substrate 42 through a p-metal layer 41, and a photodiode 3 is disposed inside this substrate 42. According to this modified example, an alignment operation for the light emitting element 1, a half mirror 2, and the photodiode 3 can become unnecessary, the size of the distance measuring device 100 can be decreased, and shock resistance of the distance measuring device 100 can be improved.

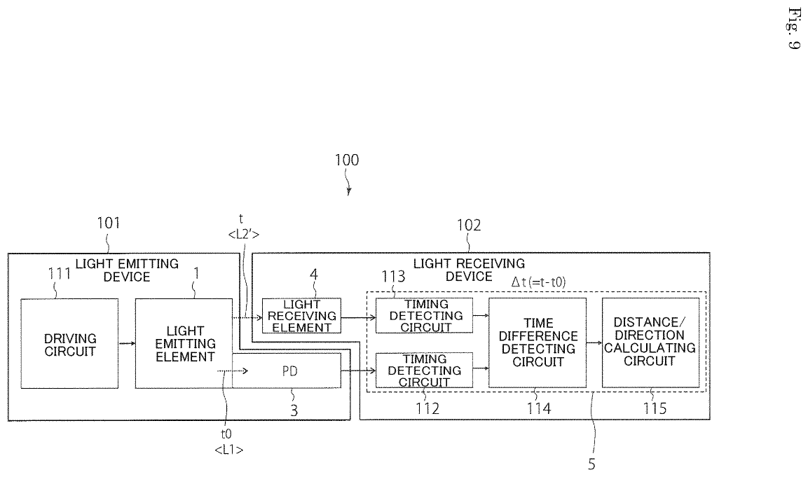

FIG. 9 is a block diagram illustrating the structure of a distance measuring device 100 of a modified example of the first embodiment.

FIG. 9 illustrates the block structure of the distance measuring device 100 illustrated in FIG. 8. FIG. 9 illustrates an appearance in which the photodiode 3 and the light emitting element 1 are integrated together. In addition, such a block structure can realize to employ the light emitting element 1 illustrated in FIG. 7 instead of employing the light emitting element 1 illustrated in B of FIG. 6.

As above, the distance measuring device 100 according to this embodiment detects an emission timing of light L2 (oscillation light) on the basis of a detection result of light L1 (excitation light). Thus, according to this embodiment, for example, detection of the emission timing of the light L2 using a low-priced photodiode 3 and the like can be performed, whereby the emission timing of the light L2 can be appropriately detected.

### Second Embodiment

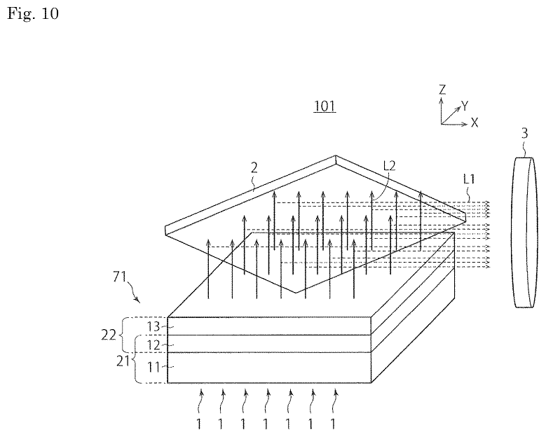

FIG. 10 is a perspective view illustrating the structure of a light emitting device 101 according to a second embodiment.

The light emitting device 101 according to this embodiment includes a plurality of light emitting elements 1, a half mirror 2, and a photodiode 3. Such light emitting elements 1 are formed using a semiconductor section 11, a solid-state laser medium 12, and a saturable absorber 13 that are common to the light emitting elements 1, thereby being arranged in a two-dimensional array form. These are called as a light emitting element array 71. Also in this embodiment, the semiconductor section 11 and the solid-state laser medium 12 form a resonator 21, and the solid-state laser medium 12 and the saturable absorber 13 form a resonator 22.

Light L emitted from each light emitting element 1 is split into light L1 and light L2 by the half mirror 2. The light L1 is detected by the photodiode 3, and the light L2 is emitted from the light emitting device 101 to the outside.

In this embodiment, the plurality of light emitting elements 1 are sequentially driven, and light L is sequentially emitted from such light emitting elements 1, In accordance with this, the light L from such light emitting elements 1 can be detected by one photodiode 3. In addition, by driving such light emitting elements 1 not simultaneously but sequentially, the amount of heat generated per light emitting element 1 can be reduced. Furthermore, by configuring the light emitting device 101 using the plurality of light emitting elements 1, the light L2 can be emitted to a broad range.

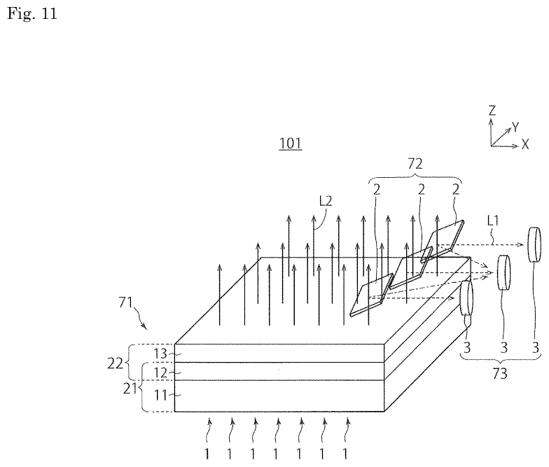

FIG. 11 is a perspective view illustrating the structure of a light emitting device 101 of a comparative example of the second embodiment.

The light emitting device 101 of this comparative example includes a plurality of light emitting elements 1, a plurality of half mirrors 2, and a plurality of photodiodes 3. These will be respectively referred to as a light emitting element array 71, a half mirror array 72, and a photodiode array 73. The light L emitted from each light emitting element 1 is split into light L1 and light L2 by a corresponding half mirror 2. The light L1 is detected by a corresponding photodiode 3, and the light L2 is emitted from the light emitting device 101 to the outside.

According to this comparative example, such light emitting elements 1 can be not only sequentially driven but also simultaneously driven. However, in this comparative example, there is a problem that it is difficult to secure a space in which the half mirrors 2 and the photodiodes 3 are arranged. In addition, in this comparative example, there is a problem that crosstalk in which light L1 to be incident in a certain photodiode 3 is incident in another photodiode 3 may occur. FIG. 11 illustrates an appearance in which crosstalk occurs between photodiodes 3. Such problems can be solved in accordance with a modified example to be described below.

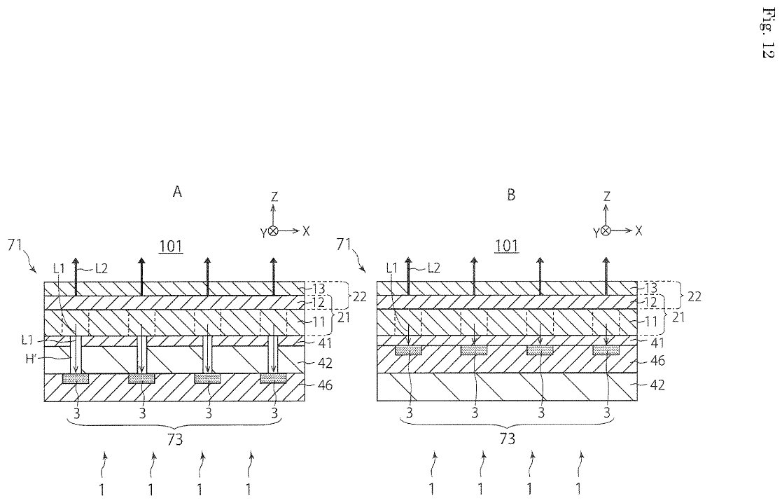

FIG. 12 is a cross-sectional view illustrating the structure of a light emitting device 101 of a modified example of the second embodiment.

In a modified example illustrated in A of FIG. 12, a light emitting device 101 includes a plurality of light emitting elements 1 and a plurality of photodiodes 3. Such light emitting elements 1 are formed using a semiconductor section 11, a solid-state laser medium 12, and a saturable absorber 13 that are common to the light emitting elements 1, and such photodiodes 3 are formed inside a photodiode layer 46 that is common to the photodiodes 3. Examples of the photodiode layer 46 include semiconductor layers such as a polysilicon layer, a compound semiconductor layer, and the like. A of FIG. 12 illustrates a light emitting element array 71 having a plurality of light emitting elements 1 arranged in a two-dimensional array form and a photodiode array 73 having a plurality of photodiodes 3 arranged in a two-dimensional array form. Also in this modified example, the semiconductor section 11 and the solid-state laser medium 12 form a resonator 21, and the solid-state laser medium 12 and the saturable absorber 13 form a resonator 22.

In addition, similar to B of FIG. 6 according to the first embodiment, A of FIG. 12 illustrates a p-metal layer 41 and a substrate 42. The semiconductor section 11, the solid-state laser medium 12, and a saturable absorber 13 are stacked in order on an upper face of the substrate 42 through the p-metal layer 41. The photodiode layer 46 is disposed on a lower face of the substrate 42. An upper face and the lower face of the substrate 42 are respective examples of a first face and a second face of the present disclosure.

Each photodiode 3 of this modified example, as illustrated in A of FIG. 12, detects light L1 that is emitted from a lower face of a corresponding light emitting element 1 and passes through an opening portion H′ of the p-metal layer 41 and the substrate 42. The light emitting element array 71 and the photodiode array 73 of this modified example are disposed on the upper face and the lower face of the same substrate 42, thereby being integrated together. According to this modified example, an alignment operation for the light emitting element 1, a half mirror 2, and the photodiode 3 can become unnecessary, the size of the distance measuring device 100 can be decreased, and shock resistance of the distance measuring device 100 can be improved. In addition, according to this modified example, by arranging each photodiode 3 near a corresponding light emitting element 1, occurrence of crosstalk can be suppressed.

In a modified example illustrated in B of FIG. 12, a light emitting device 101 has a structure similar to the light emitting device 101 illustrated in A of FIG. 12. However, a photodiode layer 46 of this modified example is disposed between an upper face of a substrate 42 and a lower face of a p-metal layer 41. According to this modified example, each photodiode 3 can be arranged further near a corresponding light emitting element 1.

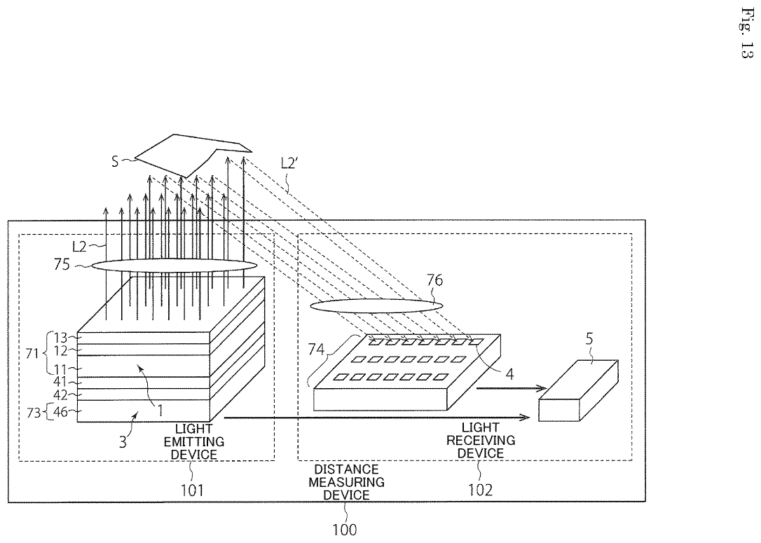

FIG. 13 is a schematic view illustrating the structure of the distance measuring device 100 according to the second embodiment.

The distance measuring device 100 (FIG. 13) according to this embodiment has a structure that is similar to the distance measuring device 100 according to the first embodiment illustrated in FIG. 8. However, the distance measuring device 100 according to this embodiment includes the light emitting device 101 illustrated in A of FIG. 12 as a light emitting device 101. For this reason, the distance measuring device 100 according to this embodiment includes the light emitting element array 71 and the photodiode array 73 inside the light emitting device 101.

In addition, the distance measuring device 100 according to this embodiment includes a light receiving element array 74 disposed inside the light receiving device 102, a lens 75 disposed inside the light emitting device 101, and a lens 76 disposed inside the light receiving device 102. The light receiving element array 74 has a plurality of light receiving elements 4 arranged in a two-dimensional array form.

The distance measuring device 100 according to this embodiment emits light L2 emitted from each light emitting element 1 to a subject S through the lens 75. The light receiving element array 74 receives light L2′ from the subject S through the lens 76. Each light receiving element 4 outputs a signal representing a light reception result of the light L2′ to the arithmetic operation circuit 5. On the other hand, each photodiode 3 outputs a signal representing a detection result of light L1 to the arithmetic operation circuit 5. Generally, although the number of arrows representing the light L2′ in FIG. 13 is the same as the number of arrows representing the light L2 in FIG. 13 when the drawing is illustrated more accurately, here, for easy understanding of the drawing, illustration of the arrows representing the light L2′ is partly omitted.

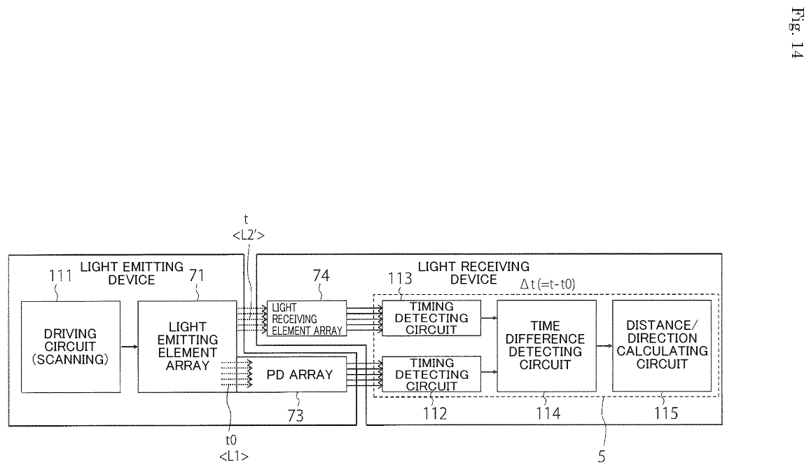

FIG. 14 is a block diagram illustrating the structure of the distance measuring device 100 according to the second embodiment.

FIG. 14 illustrates the block structure of the distance measuring device 100 illustrated in FIG. 13. Although the structure illustrated in FIG. 14 is similar to the structure according to the first embodiment illustrated in FIG. 9, FIG. 14 illustrates a light emitting element array 71, a photodiode array 73, and a light receiving element array 74 in place of the light emitting element 1, the photodiode 3, and the light receiving element 4. FIG. 14 illustrates an appearance in which the photodiode array 73 and the light emitting element array 71 are integrated together. The arithmetic operation circuit 5 according to this embodiment can operate similar to the arithmetic operation circuit 5 according to the first embodiment.

A driving circuit 111 according to this embodiment is a scanning driving circuit that sequentially drives a plurality of light emitting elements 1 included in the light emitting element array 71. In accordance with this, light L is sequentially emitted from such light emitting elements 1. In this case, the distance measuring device 100 according to this embodiment may include the light emitting device 101 illustrated in FIG. 10 or the light emitting device 101 illustrated in B of FIG. 12 instead of including the light emitting device 101 illustrated in A of FIG. 12. The scanning order when the plurality of light emitting elements 1 are sequentially driven may be any order.

Similar to the distance/direction calculating circuit 115 according to the first embodiment, a distance/direction calculating circuit 115 according to this embodiment performs distance measurement for a subject S. However, by using detection results of light L1 according to the plurality of photodiodes 3 and light reception results of light L2′ according to the plurality of light receiving element 4, the distance/direction calculating circuit 115 according to this embodiment calculates a distance between the subject S and the distance measuring device 100 and a direction of the subject S with respect to the distance measuring device 100.

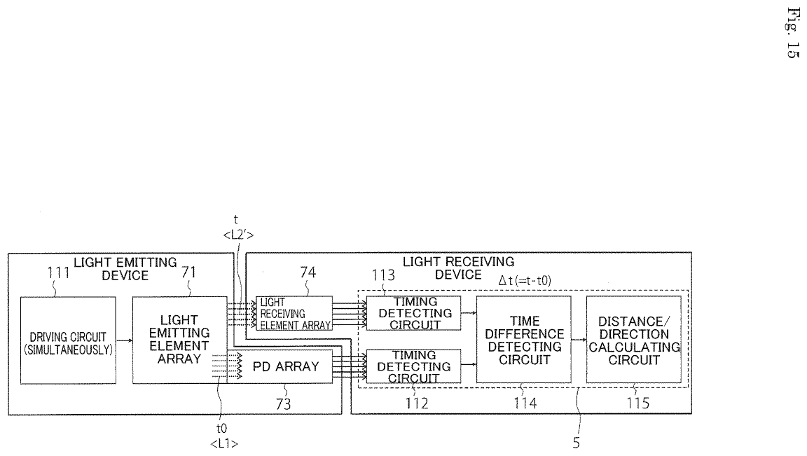

FIG. 15 is a block diagram illustrating the structure of a distance measuring device 100 of a modified example of the second embodiment.

The distance measuring device 100 according to this modified example has a block structure that is similar to the distance measuring device 100 illustrated in FIG. 14. However, the driving circuit 111 of this modified example is a simultaneous driving circuit that simultaneously drives a plurality of light emitting elements 1 included in the light emitting element array 71. In accordance with this, light L is simultaneously emitted from such light emitting elements 1. In this case, the distance measuring device 100 of this modified example may include the light emitting device 101 illustrated in B of FIG. 12 instead of including the light emitting device 101 illustrated in A of FIG. 12.

In addition, the driving circuit 111 of this modified example may simultaneously drive all the light emitting elements 1 inside the light emitting element array 71 or may simultaneously drive some of the light emitting elements 1 inside the light emitting element array 71. For example, in a case in which the light emitting element array 71 includes a plurality of groups, and each group includes a plurality of light emitting elements 1, the driving circuit 111 of this modified example may simultaneously drive light emitting elements 1 for each group. More specifically, the driving circuit 111 of this modified example may employ simultaneous driving within each group and employ sequential driving between groups such as a case in which a plurality of light emitting elements 1 within a first group are simultaneously driven, next, a plurality of light emitting elements 1 within a second group are simultaneously driven, and, next, a plurality of light emitting elements 1 within a third group are simultaneously driven.

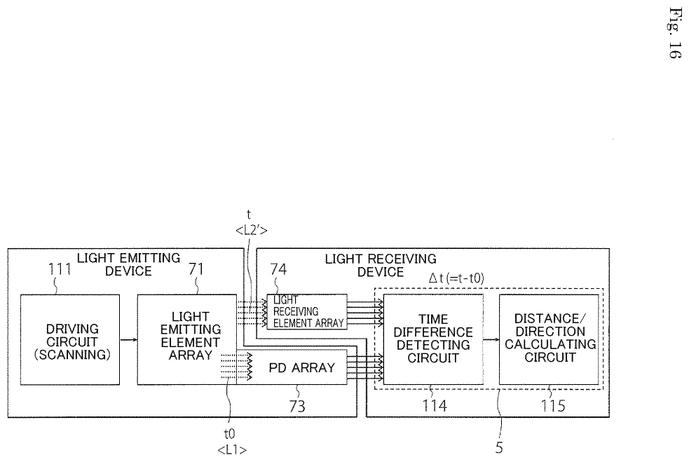

FIG. 16 is a block diagram illustrating the structure of a distance measuring device 100 of a modified example of the second embodiment.

The distance measuring device 100 of this modified example has a block structure that is similar to the distance measuring device 100 illustrated in FIG. 14. However, an arithmetic operation circuit 5 of this modified example includes a time difference detecting circuit 114 and a distance/direction calculating circuit 115 but does not include the timing detecting circuit 112 and the timing detecting circuit 113.

The time difference detecting circuit 114 of this modified example receives signals representing detection results of light L1 from the photodiode array 73 (the photodiode 3) and receives signals representing light reception results of light L2 from the light receiving element array 74 (the light receiving element 4). The time difference detecting circuit 114 of this modified example further detects a difference between the emission timing of the light L2 and the light reception timing of the light L2′ on the basis of such signals. This difference, for example, is a time difference At between the emission time to of the light L2 and the light reception time t of the light L2′ (Δt=t−t0). In this way, the time difference detecting circuit 114 of this modified example has functions similar to the functions of the timing detecting circuit 112, the timing detecting circuit 113, and the time difference detecting circuit 114 illustrated in FIG. 14. Similar to the distance/direction calculating circuit 115 illustrated in FIG. 14, the distance/direction calculating circuit 115 of this modified example performs distance measurement for a subject S on the basis of the received difference.

As above, similar to the distance measuring device 100 according to the first embodiment, the distance measuring device 100 of this embodiment detects an emission timing of light L2 (oscillation light) on the basis of a detection result of light L1 (excitation light). Thus, according to this embodiment, the emission timing of light L2 can be appropriately detected, for example, the emission timing of the light L2 can be detected using a low-priced photodiode 3 or the like. In addition, according to this embodiment, by employing the light emitting element array 71 and the photodiode array 73, sequential driving and simultaneous driving of a plurality of light emitting elements 1 can be employed. Even in a case in which a plurality of light emitting elements 1 are simultaneously driven, generally, the emission timing of the light L2 is slightly different for each light emitting element 1, and thus it is preferable to use a plurality of photodiodes 3.

### Third Embodiment

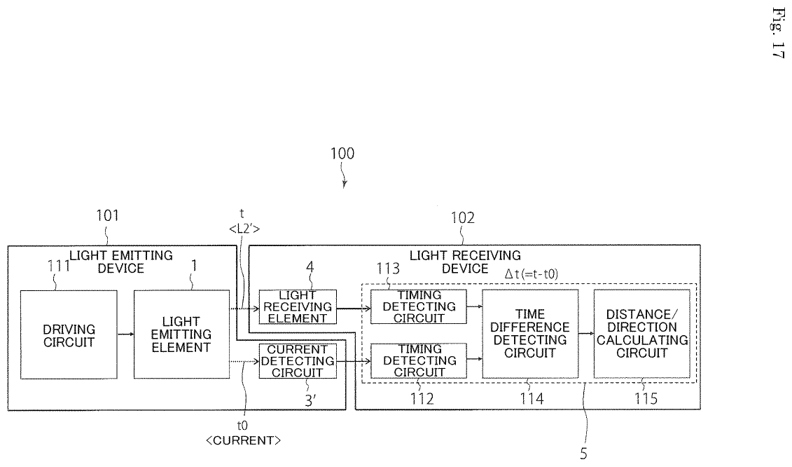

FIG. 17 is a block diagram illustrating the structure of a distance measuring device 100 according to a third embodiment.

The distance measuring device 100 (FIG. 17) of this embodiment has a structure that is similar to the distance measuring device 100 (FIG. 3) according to the first embodiment. However, the distance measuring device 100 according to this embodiment includes a current detecting circuit 3′ in place of the photodiode 3. Similar to the photodiode 3, the current detecting circuit 3′ is an example of a detector of the present disclosure.

When a light emitting element 1 is driven, the driving circuit 111 supplies a drive current to the light emitting element 1. As a result, light L (FIG. 1) is emitted from the light emitting element 1. The light L emitted from the light emitting element 1 includes not only light L2 corresponding to oscillation light but also light L1 corresponding to excitation light. A photodiode 3 according to the first embodiment detects light L1 and outputs a signal representing a detection result of the light L1 to the timing detecting circuit 112. In contrast to this, the current detecting circuit 3′ according to this embodiment detects a drive current of the light emitting element 1 and outputs a signal representing a detection result of the drive current to a timing detecting circuit 112.

In this embodiment, the timing detecting circuit 112 receives a signal representing a detection result of a drive current from the current detecting circuit 3′. In addition, the timing detecting circuit 112 detects an emission timing of light L2 on the basis of a detection result of a drive current. The timing detecting circuit 112, for example, detects an emission time to of light L2 from the light emitting element 1 as an emission timing of the light L2.

As a result of the review, it could be understood that the value of the drive current of a light emitting element 1 changes in accordance with an emission timing of light L2 from the light emitting element 1. For example, it could be checked that the value of the drive current of the light emitting element 1 changes in synchronization with the emission time to of light L2 from the light emitting element 1. Thus, in order to detect the emission timing of the light L2, the timing detecting circuit 112 receives a signal representing a detection result of the drive current. According to this embodiment, by using a phenomenon that the value of a drive current changes in accordance with an emission timing of light L2, the emission timing of the light L2 can be detected from a detection result of the drive current. A signal received by the timing detecting circuit 112 from the current detecting circuit 3′, for example, is a signal that represents a detection result of the value of the drive current.

Timings at which the value of the drive current of the light emitting element 1 changes are illustrated in FIG. 5. In FIG. 5, the photon density of light L1 is reduced at a timing denoted by a white circle, and the carrier density of the drive current also increases at the same timing. The timing at which the photon density of the light L1 reduces corresponds to a timing at which the intensity of the light L1 emitted from the light emitting element 1 reduces. On the other hand, a timing at which the carrier density of the drive current increases corresponds to a timing at which the value of the drive current increases. A reduction of the intensity of the light L1 and an increase of the value of the drive current occur at a timing at which light L2 (pulse light) is emitted from the light emitting element 1. Thus, by detecting a timing at which the value of the drive current increases, the emission timing of the light L2 from the light emitting element 1 can be detected.

Operations of the timing detecting circuit 113, the time difference detecting circuit 114, the distance/direction calculating circuit 115, and the like according to this embodiment are similar to operations thereof according to the first embodiment.

In addition, the current detecting circuit 3′ according to this embodiment may be applied to any other distance measuring device 100 instead of being applied to the distance measuring device 100 illustrated in FIG. 3 and, for example, may be applied to the distance measuring device 100 illustrated in FIG. 4, 9, 14, 15, or 16.

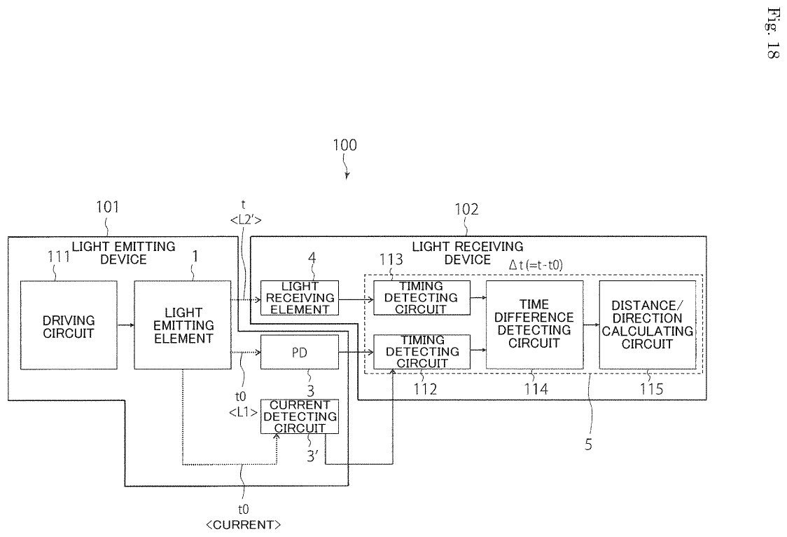

FIG. 18 is a block diagram illustrating the structure of a distance measuring device 100 of a modified example of the third embodiment.

The distance measuring device 100 illustrated in FIG. 17 includes a current detecting circuit 3′ in place of the photodiode 3. On the other hand, the distance measuring device 100 illustrated in FIG. 18 includes a current detecting circuit 3′ together with a photodiode 3. According to this modified example (FIG. 18), the emission timing of light L2 can be detected on the basis of a detection result of light L1 according to the photodiode 3 and can detect the emission timing of light L2 on the basis of a detection result of a drive current according to the current detecting circuit 3′. In other words, according to this modified example, any one of the photodiode 3 and the current detecting circuit 3′ to be used can be selected.

While embodiments of the present disclosure have been described above, these embodiments may be implemented with various modifications without departing from the spirit of the present disclosure. For example, a combination of two or more embodiments may be implemented. Here, the present disclosure may have the following configuration.
(1)

An optical device including: a light emitting element including a semiconductor section that is included in a first resonator causing light of a first wavelength to resonate and causes the light of the first wavelength to oscillate, a solid-state laser medium that is included in the first resonator and a second resonator causing light of a second wavelength to resonate and causes the light of the second wavelength to oscillate, and a saturable absorber included in the second resonator and emitting the light of the second wavelength; a detector detecting the light of the first wavelength or a drive current of the light emitting element; and an emission timing detecting unit detecting an emission timing of the light of the second wavelength on the basis of a detection result of the light of the first wavelength or the drive current of the light emitting element acquired using the detector.
(2)

The optical device described in (1), in which an intensity of the light of the first wavelength or a value of the drive current of the light emitting element changes in accordance with the emission timing of the light of the second wavelength.
(3)

The optical device described in (1), further including a distance measuring unit performing distance measurement on the basis of a detection result of the emission timing of the light of the second wavelength acquired using the emission timing detecting unit.
(4)

The optical device described in (3), further including a light receiving element receiving reflective light of the light of the second wavelength, in which the distance measuring unit performs the distance measurement on the basis of a detection result of the emission timing of the light of the second wavelength acquired using the emission timing detecting unit and a light reception result of the reflective light acquired using the light receiving element.
(5)

The optical device described in (4), further including a light reception timing detecting unit detecting a light reception timing of the reflective light on the basis of a light reception result of the reflective light acquired using the light receiving element, in which the distance measuring unit performs the distance measurement on the basis of a detection result of the emission timing of the light of the second wavelength acquired using the emission timing detecting unit and a detection result of the light reception timing of the reflective light acquired using the light reception timing detecting unit.
(6)

The optical device described in (5), further including a difference detecting unit detecting a difference between the emission timing of the light of the second wavelength and the light reception timing of the reflective light, in which the distance measuring unit performs the distance measurement on the basis of the difference detected using the difference detecting unit.
(7)

The optical device described in (1), in which the optical device is a distance measuring device performing distance measurement on the basis of a detection result of the emission timing of the light of the second wavelength acquired using the emission timing detecting unit.
(8)

The optical device described in (1), in which the optical device is a light emitting device emitting the light of the second wavelength and is included in a distance measuring device together with a light receiving device receiving the light of the second wavelength.
(9)

The optical device described in (1), in which the light emitting element includes: a first reflective layer that is positioned within the semiconductor section and reflects the light of the first wavelength; a second reflective layer that is positioned on a first face of the solid-state laser medium and reflects the light of the second wavelength; a third reflective layer that is positioned on a second face of the solid-state laser medium and reflects the light of the first wavelength; a fourth reflective layer that is positioned on a surface of the saturable absorber and reflects the light of the second wavelength; and a fifth reflective layer that is positioned within the semiconductor section, is positioned on a solid-state laser medium side of the first reflective layer, and reflects a part of the light of the first wavelength.
(10)

The optical device described in (1), in which the detector is arranged on a second resonator side of the light emitting element.
(11)

The optical device described in (1), in which the detector is arranged on a first resonator side of the light emitting element.
(12)

The optical device described in (1), in which the detector is mounted in the light emitting element.
(13)

The optical device described in (1), in which the light emitting element is disposed on a first face side of a substrate, and the detector is disposed on the first face side of the substrate and is disposed inside a layer disposed between the substrate and the light emitting element.
(14)

The optical device described in (1), in which the light emitting element is disposed on a first face side of a substrate, and the detector is disposed inside a layer disposed on a second face side of the substrate.
(15)

The optical device described in (1), in which the optical device includes a plurality of light emitting elements arranged in an array form as the light emitting element.
(16) The optical device described in (15), in which the optical device further includes a plurality of detectors arranged in an array form inside a same layer as that of the detector.
(17)

The optical device described in (15), further including a driving unit driving the plurality of light emitting elements, in which the driving unit sequentially excites light from the plurality of light emitting elements by scanning the plurality of light emitting elements.
(18)

The optical device described in (15), further including a driving unit driving the plurality of light emitting elements, in which the driving unit simultaneously excites light from the plurality of light emitting elements by simultaneously driving the plurality of light emitting elements.
(19)

A distance measuring device including: a light emitting element including a semiconductor section that is included in a first resonator causing light of a first wavelength to resonate and causes the light of the first wavelength to oscillate, a solid-state laser medium that is included in the first resonator and a second resonator causing light of a second wavelength to resonate and causes the light of the second wavelength to oscillate, and a saturable absorber included in the second resonator and emitting the light of the second wavelength; a detector detecting the light of the first wavelength or a drive current of the light emitting element; a light receiving element receiving reflective light of the light of the second wavelength; and a distance measuring unit performing distance measurement on the basis of a detection result of the light of the first wavelength or a drive current of the light emitting element acquired using the detector and a light reception result of the reflective light acquired using the light receiving element.
(20)

The distance measuring device described in (19), further including an emission timing detecting unit detecting an emission timing of the light of the second wavelength on the basis of a detection result of the light of the first wavelength or the drive current of the light emitting element acquired using the detector, and the distance measuring unit performs the distance measurement on the basis of a detection result of the emission timing of the light of the second wavelength acquired using the emission timing detecting unit and a light reception result of the reflective light acquired using the light receiving element.

### REFERENCE SIGNS LIST

1 Light emitting element
2 Half mirror
3 Photodiode
3′ Current detecting circuit
4 Light receiving element
5 Arithmetic operation circuit
11 Semiconductor section
12 Solid-state laser medium
13 Saturable absorber
21 Resonator
22 Resonator
31 n-DBR layer
32 Cladding layer
33 Active layer
34 Cladding layer
35 Oxide layer
36 p-DBR layer
41 p-metal layer
42 Substrate
43 n-contact layer
44 Substrate
45 Non-doped semiconductor layer
46 Photodiode layer
51 n-type semiconductor layer
52 Active layer
53 p-type semiconductor layer
61 n-metal layer
62 p-metal layer
63 n-metal layer
64 p-metal layer
71 Light emitting element array
72 Half mirror array
73 Photodiode array
74 Light receiving element array
75 Lens
76 Lens
100 Distance measuring device
101 Light emitting device
102 Light receiving device
111 Driving circuit
112 Timing detecting circuit
113 Timing detecting circuit
114 Time difference detecting circuit
115 Distance/direction calculating circuit

1. An optical device comprising:
a light emitting element including a semiconductor section that is included in a first resonator causing light of a first wavelength to resonate and causes the light of the first wavelength to oscillate, a solid-state laser medium that is included in the first resonator and a second resonator causing light of a second wavelength to resonate and causes the light of the second wavelength to oscillate, and a saturable absorber included in the second resonator and emitting the light of the second wavelength;
a detector detecting the light of the first wavelength or a drive current of the light emitting element; and
an emission timing detecting unit detecting an emission timing of the light of the second wavelength on the basis of a detection result of the light of the first wavelength or the drive current of the light emitting element acquired using the detector.

2. The optical device according to claim 1, wherein an intensity of the light of the first wavelength or a value of the drive current of the light emitting element changes in accordance with the emission timing of the light of the second wavelength.

3. The optical device according to claim 1, further comprising a distance measuring unit performing distance measurement on the basis of a detection result of the emission timing of the light of the second wavelength acquired using the emission timing detecting unit.

4. The optical device according to claim 3, further comprising a light receiving element receiving reflective light of the light of the second wavelength, wherein the distance measuring unit performs the distance measurement on the basis of a detection result of the emission timing of the light of the second wavelength acquired using the emission timing detecting unit and a light reception result of the reflective light acquired using the light receiving element.

5. The optical device according to claim 4, further comprising a light reception timing detecting unit detecting a light reception timing of the reflective light on the basis of a light reception result of the reflective light acquired using the light receiving element,
wherein the distance measuring unit performs the distance measurement on the basis of a detection result of the emission timing of the light of the second wavelength acquired using the emission timing detecting unit and a detection result of the light reception timing of the reflective light acquired using the light reception timing detecting unit.

6. The optical device according to claim 5, further comprising a difference detecting unit detecting a difference between the emission timing of the light of the second wavelength and the light reception timing of the reflective light, wherein the distance measuring unit performs the distance measurement on the basis of the difference detected using the difference detecting unit.

7. The optical device according to claim 1, wherein the optical device is a distance measuring device performing distance measurement on the basis of a detection result of the emission timing of the light of the second wavelength acquired using the emission timing detecting unit.

8. The optical device according to claim 1, wherein the optical device is a light emitting device emitting the light of the second wavelength and is included in a distance measuring device together with a light receiving device receiving the light of the second wavelength.

9. The optical device according to claim 1, wherein the light emitting element includes:
a first reflective layer that is positioned within the semiconductor section and reflects the light of the first wavelength:
a second reflective layer that is positioned on a first face of the solid-state laser medium and reflects the light of the second wavelength;
a third reflective layer that is positioned on a second face of the solid-state laser medium and reflects the light of the first wavelength;
a fourth reflective layer that is positioned on a surface of the saturable absorber and reflects the light of the second wavelength; and
a fifth reflective layer that is positioned within the semiconductor section, is positioned on a solid-state laser medium side of the first reflective layer, and reflects a part of the light of the first wavelength.

10. The optical device according to claim 1, wherein the detector is arranged on a second resonator side of the light emitting element.

11. The optical device according to claim 1, wherein the detector is arranged on a first resonator side of the light emitting element.

12. The optical device according to claim 1, wherein the detector is mounted in the light emitting element.

13. The optical device according to claim 1,
wherein the light emitting element is disposed on a first face side of a substrate, and
wherein the detector is disposed on the first face side of the substrate and is disposed inside a layer disposed between the substrate and the light emitting element.

14. The optical device according to claim 1,
wherein the light emitting element is disposed on a first face side of a substrate, and
wherein the detector is disposed inside a layer disposed on a second face side of the substrate.

15. The optical device according to claim 1, wherein the optical device includes a plurality of light emitting elements arranged in an array form as the light emitting element.

16. The optical device according to claim 15, wherein the optical device further includes a plurality of detectors arranged in an array form inside a same layer as that of the detector.

17. The optical device according to claim 15, further comprising a driving unit driving the plurality of light emitting elements, wherein the driving unit sequentially excites light from the plurality of light emitting elements by scanning the plurality of light emitting elements.

18. The optical device according to claim 15, further comprising a driving unit driving the plurality of light emitting elements, wherein the driving unit simultaneously excites light from the plurality of light emitting elements by simultaneously driving the plurality of light emitting elements.

19. A distance measuring device comprising:
a light emitting element including a semiconductor section that is included in a first resonator causing light of a first wavelength to resonate and causes the light of the first wavelength to oscillate, a solid-state laser medium that is included in the first resonator and a second resonator causing light of a second wavelength to resonate and causes the light of the second wavelength to oscillate, and a saturable absorber included in the second resonator and emitting the light of the second wavelength;
a detector detecting the light of the first wavelength or a drive current of the light emitting element;
a light receiving element receiving reflective light of the light of the second wavelength; and
a distance measuring unit performing distance measurement on the basis of a detection result of the light of the first wavelength or a drive current of the light emitting element acquired using the detector and a light reception result of the reflective light acquired using the light receiving element.

20. The distance measuring device according to claim 19, further comprising an emission timing detecting unit detecting an emission timing of the light of the second wavelength on the basis of a detection result of the light of the first wavelength or the drive current of the light emitting element acquired using the detector, and
wherein the distance measuring unit performs the distance measurement on the basis of a detection result of the emission timing of the light of the second wavelength acquired using the emission timing detecting unit and a light reception result of the reflective light acquired using the light receiving element.
